(19) United States
(12) Patent Application Publication
(10) Pub. No.: US 2019/0206839 A1
(43) Pub. Date: Jul. 4, 2019

(54) ELECTRONIC DEVICE PACKAGE

(71) Applicant: Intel Corporation, Santa Clara, CA (US)

(72) Inventors: Ranjul Balakrishnan, Bangalore (IN); Navneet K. Singh, Bangalore (IN); Bijendra Singh, Bangalore (IN)

(73) Assignee: Intel Corporation, Santa Clara, CA (US)

(21) Appl. No.: 15/859,258

(22) Filed: Dec. 29, 2017

(51) Int. Cl. H01L 25/065; H01L 25/18; H01L 25/00; H01L 23/367

(52) U.S. Cl. CPC H01L 25/0657; H01L 25/18; H01L 25/50; H01L 2225/06589; H01L 2225/06517; H01L 2225/06568; H01L 2225/06586; H01L 23/367

(57) ABSTRACT

Electronic device package technology is disclosed. An electronic device package in accordance with the present disclosure can include a heat spreader disposed between an electronic component and an electronic device. The heat spreader can be in thermal communication with the electronic component and operable to transfer heat from the electronic component to a lateral location beyond a first peripheral portion of the electronic component. Associated systems and methods are also disclosed.

### TECHNICAL FIELD

Embodiments described herein relate generally to electronic device packages and package on package (POP) stacks, and more particularly to cooling components of such POP stacks.

### BACKGROUND

POP integrated circuit packaging is where two or more packages are stacked and interface to route signals between the packages. This arrangement provides a space savings on a printed circuit board (PCB) and has therefore become increasingly popular for small form factor applications (e.g. smart phones, tablets, etc.) due to the higher component density that can be provided. Some POP configurations stack a memory package (e.g., DRAM, SRAM, FLASH, etc.) on a logic or processor package and are known as mixed logic-memory stacks. A logic or processor package can include processor and/or a system on a chip (SOC), which may integrate a CPU, a GPU, a memory controller, a video encoder/decoder, an audio encorder/decoder, a camera processor, system memory, and/or a modem onto a single chip.

### BRIEF DESCRIPTION OF THE DRAWINGS

Technology features and advantages will be apparent from the detailed description which follows, taken in conjunction with the accompanying drawings, which together illustrate, by way of example, various technology embodiments; and, wherein:

FIG. 1A illustrates a schematic cross-section of an electronic device package in context with a next level component and a thermal solution, in accordance with an example embodiment;

FIG. 1B illustrates an exploded view of the electronic device package of FIG. 1A isolated from other components.

FIG. 2 illustrates a perspective view of an electronic device package in accordance with an example embodiment;

FIG. 3A illustrates a top perspective view of a bottom portion the electronic device package of FIG. 2.

FIG. 3B illustrates a bottom perspective view of a top portion the electronic device package of FIG. 2.

FIGS. 4A-4D illustrate aspects of a method for making an electronic device package in accordance with an example embodiment; and

FIG. 5 is a schematic illustration of an exemplary computing system.

Reference will now be made to the exemplary embodiments illustrated, and specific language will be used herein to describe the same. It will nevertheless be understood that no limitation of the scope or to specific technology embodiments is thereby intended.

### DESCRIPTION OF EMBODIMENTS

Before specific embodiments are disclosed and described, it is to be understood that no limitation to the particular structures, process steps, or materials disclosed herein is intended, but also includes equivalents thereof as would be recognized by those ordinarily skilled in the relevant arts. It should also be understood that terminology employed herein is used for the purpose of describing particular examples only and is not intended to be limiting. The same reference numerals in different drawings represent the same element. Numbers provided in flow charts and processes are provided for clarity in illustrating steps and operations and do not necessarily indicate a particular order or sequence. Unless defined otherwise, all technical and scientific terms used herein have the same meaning as commonly understood by one of ordinary skill in the art to which this disclosure belongs.

As used in this written description, the singular forms “a,” “an” and “the” provide express support for plural referents unless the context clearly dictates otherwise. Thus, for example, reference to “a layer” includes a plurality of such layers.

In this application, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open ended term in the written description like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

The term “coupled,” as used herein, is defined as directly or indirectly connected in an electrical or nonelectrical manner. “Directly coupled” items or objects are in physical contact and attached to one another. Objects described herein as being “adjacent to” each other may be in physical contact with each other, in close proximity to each other, or in the same general region or area as each other, as appropriate for the context in which the phrase is used.

Occurrences of the phrase “in one embodiment,” or “in one aspect,” herein do not necessarily all refer to the same embodiment or aspect.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, sizes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

Furthermore, the described features, structures, or characteristics may be combined in any suitable manner in one or more embodiments. In this description, numerous specific details are provided, such as examples of layouts, distances, network examples, etc. One skilled in the relevant art will recognize, however, that many variations are possible without one or more of the specific details, or with other methods, components, layouts, measurements, etc. In other instances, well-known structures, materials, or operations are not shown or described in detail but are considered well within the scope of the disclosure.

### Example Embodiments

An initial overview of technology embodiments is provided below and specific technology embodiments are then described in further detail. This initial summary is intended to aid readers in understanding the technology more quickly but is not intended to identify key or essential features of the technology nor is it intended to limit the scope of the claimed subject matter.

Although mixed memory-logic POP stacks are in widespread use, a typical mixed memory-logic POP stack has poor thermal performance, which limits processor performance. With a memory package mounted on top of a logic package, direct access to a top of the logic package is blocked. As a result, the top of the logic package is not accessible for thermally coupling with a thermal solution (e.g., a heat sink, heat pipe, etc.). Typical thermal solutions for mixed memory-logic POP stacks dissipate heat by thermally coupling (i.e., making contact) with the memory package. However, high thermal resistance between the logic package processor and the memory package effectively blocks or severely limits the heat dissipation from the processor. In addition, many POP stacks encapsulate the logic package components with low thermal conductivity material, which results in minimal heat spreading inside the POP stacks. As a result of these thermal limitations, instead of conducting heat through the memory package to an associated thermal solution, most of the heat generated by the processor is conducted through the logic package substrate and interconnect structures (e.g., ball grid array (BGA)) and into the underlying PCB, which is an inefficient cooling mechanism. This inability to effectively cool the processor limits its performance.

Accordingly, a electronic device packages are disclosed that facilitate heat transfer from a heat source laterally through the package to a periphery of the package. In one aspect, heat can be transferred to a top of the package for dissipation or removal by a thermal solution. In one example, an electronic device package in accordance with the present disclosure can include a substrate. The electronic device package can also include an electronic component mounted on the substrate and operable to generate heat (e.g. due to resistance of electric current). The electronic component can have a first peripheral portion. The electronic device package can further comprise an electronic device supported by the substrate and disposed about a top side of the electronic component. The electronic device can have a second peripheral portion that extends laterally beyond the first peripheral portion. The electronic device package can also comprise a heat spreader disposed between the electronic component and the electronic device in thermal communication with the electronic component. The heat spreader can be operable to transfer heat from the electronic component to a lateral location beyond the first peripheral portion. Additionally, the electronic component can comprise a thermal conduit thermally coupled to the heat spreader at the lateral location. The thermal conduit can be operable to transfer heat away from the substrate. Associated systems and methods are also disclosed.

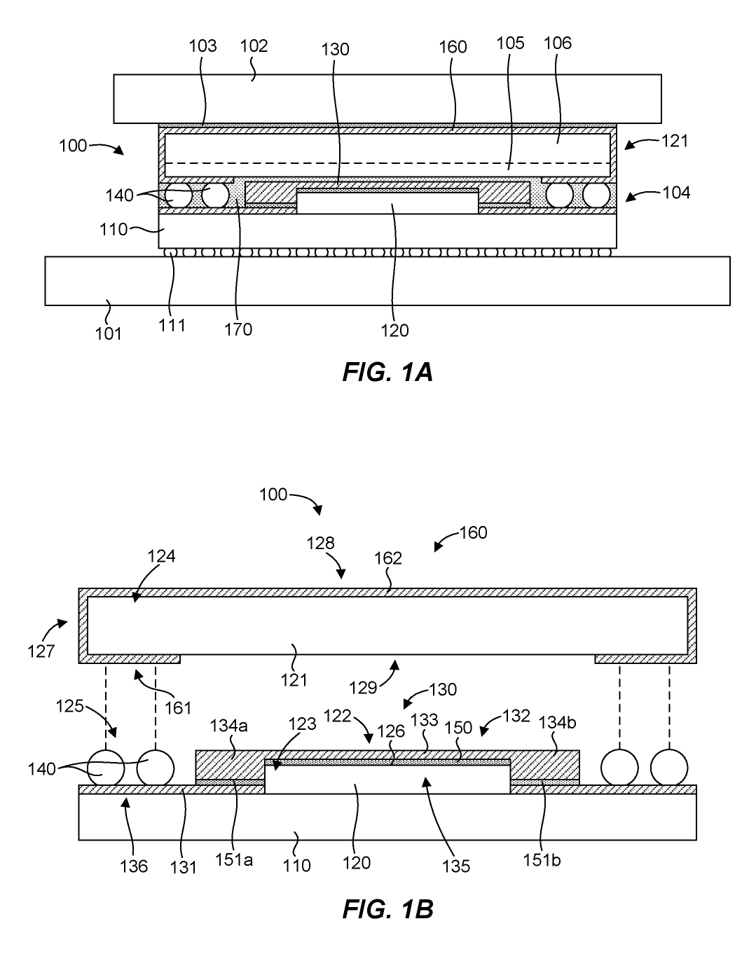

Referring to FIGS. 1A and 1B, an exemplary electronic device package 100 is schematically illustrated in cross-section. FIG. 1A shows the package 100 in the context of a next level component 101 (e.g., a substrate or circuit board such as a motherboard) to which the package may be mounted or coupled. A thermal solution 102 (e.g., a heat sink, a heat spreader, a passive/active cooling system, etc.) may be thermally coupled to a top of the package 100, such as a via a thermal interface material (TIM) 103. An exploded view of the package 100 isolated from other components is shown in FIG. 1B.

The electronic device package 100 can include a substrate 110. The electronic device package 100 can also include one or more electronic components 120 mounted on (e.g., disposed on and electrically coupled to) the substrate 110. The electronic device package 100 can further include an electronic device 121 supported by the substrate 110 and disposed about a top side 122 of the electronic component 120. In some embodiments, the electronic device 121 can be electrically coupled to the substrate 110. The electronic component 120 is a heat-generating component that generates heat during operation (e.g. due to resistance of electric current). The electronic device package 100 can include a heat spreader 130 disposed between the electronic component 120 and the electronic device 121 and in thermal communication with the electronic component 120 to facilitate cooling the electronic component 120, which is between the substrate 110 and the electronic device 121.

In some embodiments, the substrate 110 can be a package substrate and the electronic component 120 can be mounted on the substrate 110 to make up, form, or be part of an electronic device package 104. Similarly, in some embodiments, the electronic device 121 can be or include components of an electronic device package. In this case, shown in FIG. 1A, the electronic device 121 can include a package substrate 105, and one or more electronic components 106 mounted on the package substrate 105. Thus, in a particular embodiment, the electronic device package 100 can be a POP comprising a stack of electronic device packages 104, 121. In one example, the electronic device 121 can be a memory (e.g., DRAM, SRAM, FLASH, etc.) package stacked on top of the electronic device package 104, which can be a logic or processor package to form a mixed logic-memory stack. Although the electronic device 121 is shown and discussed in the present disclosure as an electronic device package, it should be understood that the electronic device 121 can be or include any suitable type of electronic device, such as an electrical component (e.g., active or passive). In some embodiments, the electronic device 121 can be an entire electronic device package of any suitable configuration (e.g., a single package or multiple packages, such as a POP), and/or one or more electronic components.

In general, an electronic component can be any electronic component or device. Thus, an electronic component can be any electronic device or component that may be included in an electronic device package, such as a semiconductor device (e.g., a die, a chip, a processor, computer memory, a platform controller hub, etc.). In one embodiment, one or more of the electronic components may represent a discrete chip, which may include an integrated circuit. The electronic components may be, include, or be a part of a processor (e.g., a CPU, a GPU, etc.), a computer memory device (e.g., ROM, SRAM, DRAM, flash memory, EEPROM, etc.), an application specific integrated circuit (ASIC), a platform controller hub (PCH), a field programmable gate array (FPGA), a modem, a system on a chip (SOC), a system in a package (SIP), or a package on a package (POP) in some embodiments. An electronic component can be any passive electronic device or component, such as a capacitor, resistor, etc. It should be recognized that any suitable number of electronic components can be included. In a particular embodiment, the electronic component 120 comprises one or more processors (e.g., in a SOC), and the electronic device 121 comprises one or more computer memory components.

A substrate as disclosed herein may be of any suitable construction or material. For example, a substrate may include typical substrate materials. In some embodiments, a substrate may be configured as an epoxy-based laminate substrate having a core and/or build-up layers. A substrate may be configured as other suitable type of substrate in other embodiments. For example, a substrate can be formed primarily of any suitable semiconductor material (e.g., a silicon, gallium, indium, germanium, or variations or combinations thereof, among other substrates), one or more insulating layers, such as glass-reinforced epoxy, such as FR-4, polytetrafluoroethylene (Teflon), cotton-paper reinforced epoxy (CEM-3), phenolic-glass (G3), paper-phenolic (FR-1 or FR-2), polyester-glass (CEM-5), ABF (Ajinomoto Build-up Film), any other dielectric material, such as glass, or any combination thereof, such as can be used in printed circuit boards (PCBs). In some embodiments, a substrate can be constructed primarily of silicon and/or may be configured as an interposer or a redistribution layer (RDL).

An electronic component can be electrically coupled to a substrate according to a variety of suitable configurations including a flip-chip configuration, wire bonding, and the like. One or more electronic components can be electrically coupled to a substrate using interconnect structures (e.g., solder balls or bumps and/or wire bonds) configured to route electrical signals between the electronic components and the substrate. In some embodiments, the interconnect structures may be configured to route electrical signals such as, for example, I/O signals and/or power or ground signals associated with the operation of the electronic components. In one aspect, multiple electronic components can be in a stacked relationship, for example, to save space and enable smaller form factors. It should be recognized that any suitable number of electronic components can be included in a stack. At least some of the stacked electronic components can be wirebond based integrated circuits (e.g., ASIC, DRAM, and NAND). Such wirebond based integrated circuits can be electrically coupled to one another by wirebond connections.

A substrate may include electrically conductive elements or electrical routing features configured to route electrical signals to or from the electronic components. The electrical routing features may be internal (e.g., disposed at least partially within a thickness of a substrate) and/or external to a substrate. For example, in some embodiments, a substrate may include electrical routing features such as pads, vias, and/or traces configured to receive the interconnect structures and route electrical signals to or from the electronic components. The pads, vias, and traces can be constructed of the same or similar electrically conductive materials, or of different electrically conductive materials. Any suitable electrically conductive material can be utilized, such as copper, gold, etc. In some embodiments, a substrate can include a solder resist material or other surface treatment forming an outer layer of the substrate.

The electronic device package 100 can also include interconnect structures 111, such as solder balls, coupled to a bottom side of the substrate 110 to facilitate electrically coupling the electronic device package 100 with an external electronic component, such as the next level component 101 for power and/or signaling.

As shown in FIG. 1B, the electronic component 120 can have a peripheral portion 123, and the electronic device 121 can have a peripheral portion 124 that extends laterally equal with or beyond the peripheral portion 123. The electronic device 121 therefore laterally overlaps and can extend beyond at least a portion of the electronic component 120, which can increase the difficulty in cooling the electronic component 120. The heat spreader 130, which is disposed between the electronic component 120 and the electronic device 121, is in thermal communication with the electronic component 120 and can be operable to transfer heat from the electronic component 120 to a lateral location 125 beyond the peripheral portion 123. In general, the heat spreader 130 can be configured to spread heat generated by the electronic component 120 laterally outward inside the package 100 toward a periphery of the electronic device package 100. This can be accomplished by increasing the heat transfer area utilizing a high thermal conductivity material between the substrate 110 and the electronic device 121, which reduces thermal resistance. By spreading heat in this manner, the heat spreader 130 can reduce heat flux and the junction temperature between the electronic component 120 and the electronic device 121.

The electronic device package 100 can also include a thermal conduit 140 thermally coupled to the heat spreader 130 at the lateral location 125. The thermal conduit 140 can be operable to transfer heat from the heat spreader 130 away from the substrate 110. For example, the lateral location 125 can be proximate the peripheral portion 124 of the electronic device 121 and the thermal conduit 140 can be operable to transfer heat from the heat spreader 130 toward the peripheral portion 124.

In some embodiments, the electronic device package 100 can include a heat spreader 160 disposed about the electronic device 121. The heat spreader 160 can be thermally coupled to the thermal conduit 140, for example, at the peripheral portion 124. The heat spreader 160 can spread heat about at least a portion of the electronic device 121, such as about portions of a side and/or a top of the electronic device 121. For example, the heat spreader 160 can be disposed about at least a lateral side 127 of the electronic device 121. Optionally, the heat spreader 160 can also be disposed about a top side 128 of the electronic device 121. As shown in FIG. 1A, the heat spreader 160 can be thermally coupled to the thermal solution 102.

In one aspect, the present disclosure presents structures that provide two-stage cooling of the electronic component 120. The first stage includes the heat spreader 130, which provides a low thermal resistance path and large heat transfer area for spreading heat laterally outward and away from the electronic component 120 within the package 100 (i.e., between or along the substrate 110 and the electronic device 121). The second stage includes the thermal conduit 140 and, optionally, the heat spreader 160 associated with the electronic device 121, which provides a thermal path away from the substrate 110 (e.g., about a periphery of the package 100 to the top of the electronic device 121) where heat can be dissipated more effectively (e.g., by the thermal solution 102). As a result, thermal headroom for the electronic component 120 can be increased, which can allow the electronic component 120 to operate at higher performance for longer duration using passive heat dissipation techniques.

The heat spreader 130 can have any suitable structure or configuration. In one aspect, the heat spreader 130 can cover or be disposed on at least a portion of the electronic component 120. In another aspect, the heat spreader 130 can cover or be disposed on a portion of the substrate 110. In one embodiment, the heat spreader 130 can comprise a layer 131 of thermally conductive material disposed on the substrate 110 and/or on the electronic component 120. In a particular embodiment, the layer 131 of thermally conductive material can be a layer of the substrate 110, which is exposed. A layer 131 of thermally conductive material can have any suitable thickness, such as from about 50 μm to about 130 μm in one embodiment.

In some embodiments, the heat spreader 130 can include a cover 132 with a top portion 133 and a side portion 134a, 134b defining a recess 135 that receives at least a portion of the electronic component 120 therein. The top portion 133 can be proximate to a top surface 126 of the electronic component 120. Thermal interface material (TIM), solder, thermal adhesive, etc. can be disposed between the top surface 126 of the electronic component 120 and the top portion 133 of the cover 132 at 150 to facilitate heat transfer between the electronic component 120 and the cover 132. Similarly, TIM, solder, thermal adhesive, etc. can be disposed between the respective side portions 134a, 134b of the cover 132 and the layer 131 of thermally conductive material at 151a, 151b to facilitate heat transfer between the cover 132 and the layer 131 of thermally conductive material. Thus, the heat spreader 130 can be configured to spread heat from the electronic component 120 (e.g., via the cover 132) to the substrate 110 (i.e., the layer 131 of thermally conductive material), which can provide a large heat transfer area and low thermal resistance to facilitate moving heat toward a periphery of the electronic device package 100. It should be recognized that any or all of the side portions 134a, 134b of the cover 132 can be configured to extend laterally any suitable distance from the electronic component 120. In one embodiment, a side portion can be configured to contact the thermal conduit 140.

The heat spreader 160 can have any suitable structure or configuration. In one embodiment, the heat spreader 160 can include a layer 162 of thermally conductive material, which can be disposed on at least the lateral side 127 of the electronic device 121 and, optionally, disposed about the top side 128 of the electronic device 121. The layer 162 of thermally conductive material can have any suitable thickness, such as from about 50 μm to about 100 μm in one embodiment.

The heat spreaders 130, 160 and the thermal conduit 140 can be constructed of any suitable thermally conductive material, such as copper, silver, gold, iron, graphite (e.g., natural and pyrolytic), graphene, diamond (e.g., particles and amorphous), etc., alone or in any combination. In one aspect, at least a portion of the heat spreader 130, such as the cover 132, can also serve as electromagnetic interference (EMI) shielding to reduce cross-talk among electronic devices, electrical routing features, and interconnect structures.

The thermal conduit 140 can be thermally coupled to the heat spreaders 130, 160 in any suitable manner. For example, the thermal conduit 140 and the heat spreader 130 and/or the heat spreader 160 can be directly coupled to one another (e.g., with solder, thermal adhesive, etc.), integrally formed with one another, a TIM disposed between the thermal conduit 140 and the heat spreader 130 and/or the heat spreader 160, etc. In one embodiment, the heat spreaders 130, 160 can include respective contact pads 136, 161 configured to interface with the thermal conduit 140. The contact pad 136 can be located on a top side of the substrate 110, such as at the lateral location 125 beyond the peripheral portion 123 of the electronic component 120. The contact pad 161 can be disposed on a bottom side 129 of the electronic device 121, such as in the peripheral portion 124 of the electronic device 121.

The thermal conduit 140 can have any suitable shape or configuration, such as a cuboid, sphere, cylinder, cone, etc. In a particular embodiment, the thermal conduit 140 can comprise one or more solder balls, which can be disposed on or otherwise coupled to the contact pad 136 and/or the contact pad 161. A solder ball thermal conduit can comprise an inactive or non-energized solder ball that does not carry an electrical current or signal, such as a ground solder ball and/or a dummy solder ball.

As shown in FIG. 1A, the electronic device package 100 can optionally include an encapsulant material 170. The encapsulant material 170 can be disposed on the substrate 110 and at least partially encapsulating the electronic component 120, the heat spreader 130, and/or the thermal conduit 140. The encapsulant material 170 can comprise any suitable material, such as a mold compound material (e.g., an epoxy). In some embodiments, encapsulant material 170 can be configured to provide thermal conductivity, such as by including particles of thermally conductive materials (e.g., copper, silver, gold, iron, diamond, etc.). In one aspect, TIM can be disposed between interfacing components and/or in any suitable void between components. The heat spreader 130 and optionally the encapsulant material and/or TIM can provide relatively high thermally conductive materials between the substrate 110 and the electronic device 121, which is a space where low thermally conductive materials typically exist (e.g., air, insulating mold compound, etc.).

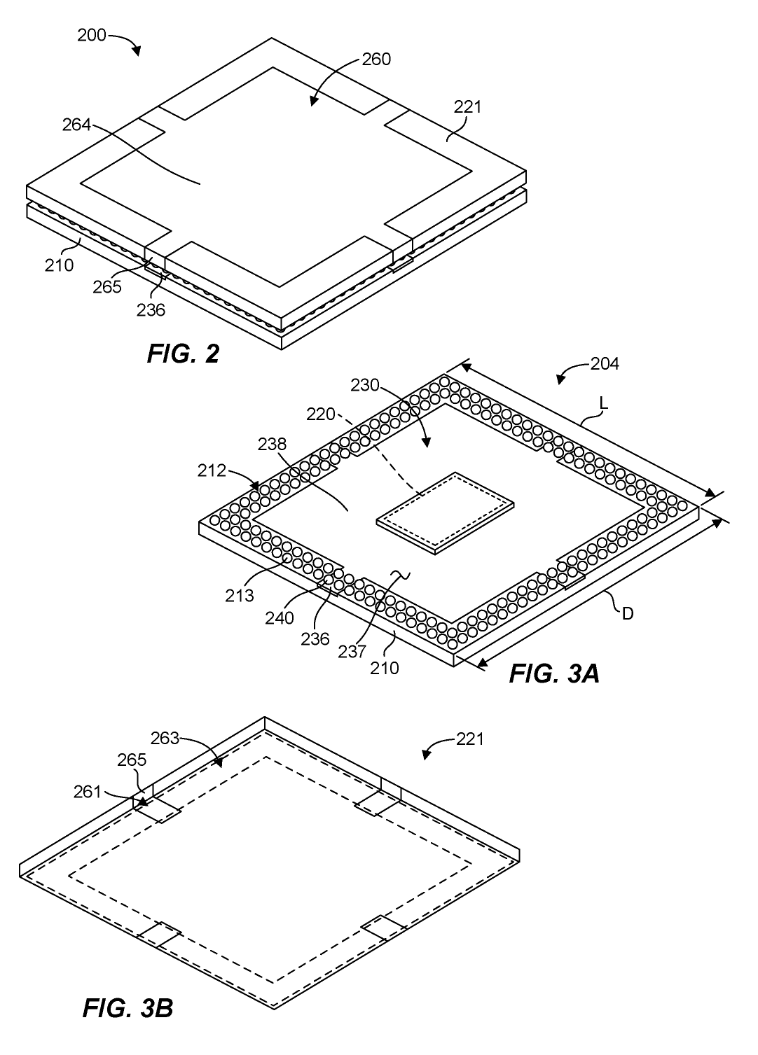

FIG. 2 illustrates a top perspective view of an electronic device package 200 in accordance with an example of the present disclosure. FIG. 3A shows a top perspective view of a bottom portion of the package 200, which includes a substrate 210 and an electronic component 220 (e.g., a package 204). FIG. 3B shows a bottom perspective view of a top portion of the package 200, which includes an electronic component (e.g., a package) 221. The electronic device package 200 includes the components and features discussed in the electronic device package 100, which is schematically illustrated in FIGS. 1A and 1B. FIGS. 2-3B show three-dimensional representations of an embodiment of an electronic device package in accordance with the present disclosure.

In one aspect, the heat spreader 230 can occupy a significant area of the substrate 210. For example, a projected area 237 of the heat spreader 230 onto the substrate 210 can be at least 50% of a top surface area (i.e., length L multiplied but width D) of the substrate 210. The area 237 of the heat spreader 230 combined with the thickness of the heat spreader 230 can provide a relatively large heat transfer area to effectively move heat from the electronic component 220 outward toward a periphery of the package 200.

Thermal conduits 240 can be mounted on contact pads 236 of the heat spreader 230. One or more contact pads 236 can be located about a periphery of the substrate 210. In one aspect, the contact pads 236 can be located in an interconnect region 212 of the substrate 210 that includes electrical routing features (e.g., pads, traces, etc.) and active interconnect structures (e.g., solder balls 213) for electrically coupling the electronic device 221 with the substrate 210. The thermal conduits 240 can be inactive ground or dummy solder balls coupled to the contact pads 236. The contact pads 236 can extend from a large, main body portion 238 of the heat spreader 230 and into the interconnect region 212 to facilitate thermally coupling with the heat spreader 260 via the thermal conduits 240. The thermal conduits 240 and contact pads 236 can be separated from the interconnect structures 236 and associated electrical routing features to prevent electrical short circuits.

In some embodiments, one or more contact pads 261 can be located about a periphery of the electronic device 221. In one aspect, the contact pads 261 can be located in an interconnect region 263 that includes electrical routing features (e.g., pads, traces, etc.) for electrically coupling the electronic device 221 with the substrate 210. The contact pads 236 can be separated from the electrical routing features to prevent electrical short circuits. Although the thermal conduits 240 and the solder balls 213 are shown associated with (e.g., mounted on) the substrate 210, it should be recognized that the thermal conduits 240 and/or the solder balls 213 can be associated with the electronic device 221. In the illustrated embodiment, the contact pads 261 can be connected to a large, top portion 264 of the heat spreader 260 via a strip 265 of thermally conductive material that extends up a side of the electronic device 221 and inward along the top of the electronic device 221. In some embodiments, the top portion 264 of the heat spreader 260 can be sized and configured to interface with a thermal solution, such as a heat sink.

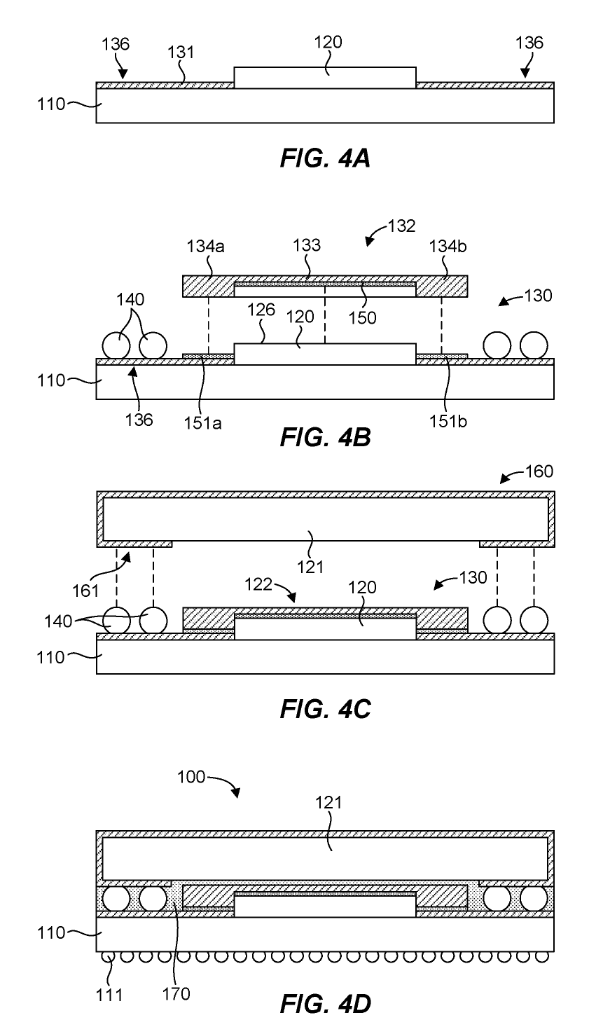

FIGS. 4A-4D schematically illustrate aspects of exemplary methods or processes for making an electronic device package, such as the electronic device package 100. FIG. 4A illustrates a side cross-sectional view of the substrate 110, which may be obtained as an initial step in the process. As described above, the substrate 110 can have any suitable configuration, such as including electrical routing features (e.g., pads, vias, and/or traces), and can be constructed of any suitable material. The electronic component 120 (e.g., a processor, SOC, etc.) can also be mounted on the substrate 110, for example, such that the electronic component 120 is electrically coupled to the substrate 110. The electronic component 120 can be mounted on the substrate 110 utilizing any suitable process or technique, such as a die attach process, a film cure process, wire bonding, solder bumping, etc.

The layer 131 of thermally conductive material can be formed to construct the heat spreader 130. The layer 131 of thermally conductive material can be formed by any suitable technique or process, such as a deposition process (e.g., plating, printing, sputtering, etc.), a molding process, a casting process, etc. In one embodiment, the layer 131 of thermally conductive material can be formed by disposing a thin metal sheet or other preformed structure on the substrate 110, which can be secured by an adhesive. In another embodiment, the layer 131 of thermally conductive material can be an existing layer (e.g., a top metal layer) of the substrate 110. The portion of the heat spreader 130 that includes the layer 131 of thermally conductive material can therefore be formed by exposing the layer 131, which can be accomplished by any suitable technique or process, such as an etching, thermal cladding and deposition process. In some embodiments, the layer 131 of thermally conductive material can extend over, and cover the electronic component 120.

In some embodiments, the heat spreader 130 includes separate cover 132 over the electronic component 120. The cover 132 can be manufactured by any suitable technique or process, such as machining (e.g., milling, electrical discharge machining, etc.), water jet cutting, stamping, or any other suitable material removal and/or forming process.

As shown in FIG. 4B, TIM, solder, thermal adhesive, etc. can be disposed on the respective side portions 134a, 134b of the cover 132 and/or the layer 131 of thermally conductive material at 151a, 151b to facilitate heat transfer between the cover 132 and the layer 131 of thermally conductive material, which form at least part of the heat spreader 130. TIM, solder, thermal adhesive, etc. can also be disposed on the top surface 126 of the electronic component 120 and/or the top portion 133 of the cover 132 inside the recess 135 at 150 to thermally couple the electronic component 120 and heat spreader 130. The cover 130 can be disposed over the electronic component 120 such that the electronic component 120 is received at least partially within the recess 135, with the top portion 133 proximate to the top surface 126 of the electronic component 120.

In addition, the thermal conduit 140 (e.g., solder balls) can be thermally and mechanically coupled to the contact pad 136 (FIG. 4B) of the heat spreader 130 and/or to the contact pad 161 of the heat spreader 160 (FIG. 4C).

With reference to FIG. 4C, the heat spreader 160 can be disposed about or formed on the electronic device 121. The heat spreader 160 can be disposed about or formed on the electronic device 121 by any suitable technique or process, such as a deposition process (e.g., plating, printing, sputtering, etc.), a molding process, a casting process, etc. In one embodiment, the heat spreader 160 can be disposed about or formed on the electronic device 121 by disposing a thin metal sheet or other preformed structure on the electronic device 121, which can be secured by an adhesive. The heat spreader 160 can be formed as a unitary structure or in portions by any combination of techniques or processes.

The electronic device 121 and associated heat spreader 160 can then be disposed about the top side 122 of the electronic component 120 and operably coupled to the substrate 110 via active interconnect structures, such as solder balls (not shown). The heat spreader 160 can also be thermally coupled to the heat spreader 130 via the thermal conduit 140 (e.g., inactive or dummy solder balls).

With the electronic device 121 coupled to the substrate 110, as shown in FIG. 4D, the encapsulant material 170 can be disposed in at least some space between the substrate 110 and the electronic device 121. The encapsulant material 170 can be applied by any suitable process or technique, such as a molding process. In one aspect, TIM can be disposed between interfacing components and/or in any suitable void between components. In one embodiment, the encapsulant material 170 can be disposed on the heat spreader 130 (e.g., over the cover 132 and the electronic component 120) prior to coupling the electronic device 121 to the substrate 110, which is illustrated in FIG. 4C.

As further shown in FIG. 4D, interconnect structures (e.g., such as solder balls 111) can be disposed on or coupled to a bottom side of the substrate 110 to facilitate electrically coupling with an external electronic component in order to arrive at the completed electronic device package 100.

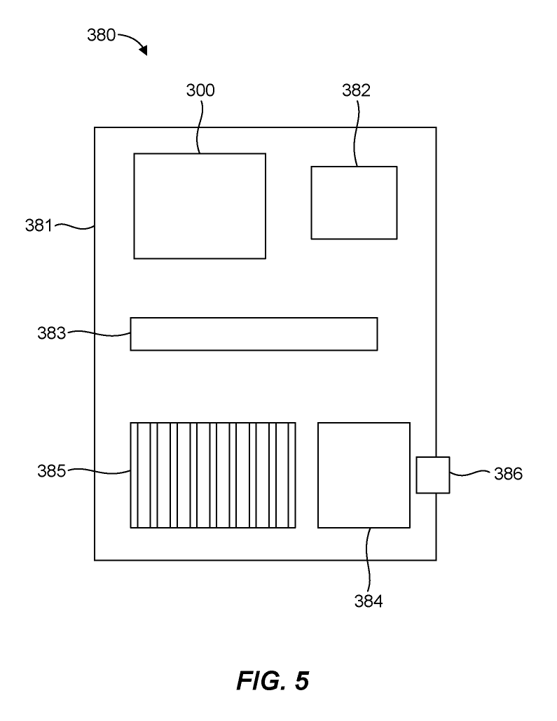

FIG. 5 schematically illustrates an example computing system 380. The computing system 380 can include an electronic device package 300 as disclosed herein, operably coupled to a motherboard 381. In one aspect, the computing system 380 can also include a processor 382, a memory device 383, a radio 384, a cooling system (e.g., a heat sink and/or a heat spreader) 385, a port 386, a slot, or any other suitable device or component, which can be operably coupled to the motherboard 381. The computing system 380 can comprise any type of computing system, such as a portable computer, a desktop computer, a mobile telephone, a digital camera, a digital music player, a tablet computer, a personal digital assistant, a pager, an instant messaging device, a wearable electronic device, a server, a television, an audio/video streaming device, or other devices. Other embodiments need not include all of the features specified in FIG. 5, and may include alternative features not specified in FIG. 5.

### Examples

The following examples pertain to further embodiments.

In one example, there is provided an electronic device package comprising a substrate, an electronic component mounted on the substrate and operable to generate heat due to resistance of electric current, the electronic component having a first peripheral portion, an electronic device supported by the substrate and disposed about a top side of the electronic component, the electronic device having a second peripheral portion that extends laterally beyond the first peripheral portion, a heat spreader disposed between the electronic component and the electronic device in thermal communication with the electronic component, the heat spreader being operable to transfer heat from the electronic component to a lateral location beyond the first peripheral portion, and a thermal conduit thermally coupled to the heat spreader at the lateral location and operable to transfer heat away from the substrate.

In one example of an electronic device package, the lateral location is proximate the second peripheral portion.

In one example of an electronic device package, the thermal conduit is operable to transfer heat from the heat spreader toward the second peripheral portion.

In one example of an electronic device package, the heat spreader comprises a contact pad that interfaces with the thermal conduit.

In one example of an electronic device package, the heat spreader comprises a layer of thermally conductive material.

In one example of an electronic device package, the layer of thermally conductive material is disposed at least on the substrate.

In one example of an electronic device package, the layer of thermally conductive material is disposed on the electronic component.

In one example of an electronic device package, the thermally conductive material comprises copper, silver, gold, iron, graphite, graphene, diamond, or a combination thereof.

In one example of an electronic device package, the layer of thermally conductive material has a thickness of from about 50 μm to about 100 μm.

In one example of an electronic device package, a projected area of the heat spreader onto the substrate is at least 50% of a top surface area of the substrate.

In one example of an electronic device package, the heat spreader comprises a cover with a top portion and a side portion defining a recess that receives at least a portion of the electronic component therein.

In one example of an electronic device package, the top portion is proximate to a top surface of the electronic component.

In one example, an electronic device package comprises thermal interface material (TIM) disposed between the top surface of the electronic component and the top portion of the cover to facilitate heat transfer therebetween.

In one example of an electronic device package, the cover is made of copper, silver, gold, iron, graphite, graphene, diamond, or a combination thereof.

In one example of an electronic device package, the thermal conduit comprises at least one solder ball.

In one example of an electronic device package, the at least one solder ball comprises a ground solder ball, a dummy solder ball, or a combination thereof.

In one example, an electronic device package comprises a second heat spreader disposed about the electronic device and thermally coupled to the thermal conduit.

In one example of an electronic device package, the second heat spreader is disposed about at least a lateral side of the electronic device.

In one example of an electronic device package, the second heat spreader is disposed about a top side of the electronic device.

In one example of an electronic device package, the second heat spreader comprises a contact pad that interfaces with the thermal conduit.

In one example of an electronic device package, the contact pad is disposed on a bottom side of the electronic device.

In one example of an electronic device package, the second heat spreader comprises a layer of thermally conductive material.

In one example of an electronic device package, the layer of thermally conductive material is disposed at least on a lateral side of the electronic device.

In one example of an electronic device package, the layer of thermally conductive material is disposed on a top side of the electronic device.

In one example of an electronic device package, the thermally conductive material comprises copper, silver, gold, iron, graphite, graphene, diamond, or a combination thereof.

In one example of an electronic device package, the layer of thermally conductive material has a thickness of from about 50 μm to about 100 μm.

In one example, an electronic device package comprises an encapsulant material disposed between the substrate and the electronic device.

In one example of an electronic device package, the encapsulant material comprises a mold compound material.

In one example of an electronic device package, the mold compound material comprises an epoxy.

In one example of an electronic device package, the electronic component comprises a processor.

In one example of an electronic device package, the electronic component comprises an integrated circuit.

In one example of an electronic device package, the electronic component comprises a system on a chip (SOC).

In one example of an electronic device package, the electronic device comprises a second substrate and a second electronic component mounted on the second substrate.

In one example of an electronic device package, the electronic device comprises computer memory.

In one example of an electronic device package, the electronic device comprises a plurality of electronic components.

In one example, an electronic device package comprises interconnect structures electrically coupling the electronic device with the substrate.

In one example of an electronic device package, the interconnect structures comprise solder balls.

In one example, an electronic device package comprises interconnect structures coupled to a bottom side of the substrate to facilitate electrically coupling the electronic device package with an external electronic component.

In one example of an electronic device package, the interconnect structures comprise solder balls.

In one example, there is provided a computing system comprising a motherboard and an electronic device package operably coupled to the motherboard, the electronic device package comprising a substrate, an electronic component mounted on the substrate and operable to generate heat due to resistance of electric current, the electronic component having a first peripheral portion, an electronic device supported by the substrate and disposed about a top side of the electronic component, the electronic device having a second peripheral portion that extends laterally beyond the first peripheral portion, a heat spreader disposed between the electronic component and the electronic device in thermal communication with the electronic component, the heat spreader being operable to transfer heat from the electronic component to a lateral location beyond the first peripheral portion, and a thermal conduit thermally coupled to the heat spreader at the lateral location and operable to transfer heat away from the substrate.

In one example of a computing system, the computing system comprises a portable computer, a desktop computer, a mobile telephone, a digital camera, a digital music player, a tablet computer, a personal digital assistant, a pager, an instant messaging device, a wearable electronic device, a server, a television, an audio/video streaming device, or a combination thereof.

In one example of a computing system, the computing system further comprises a processor, a memory device, a cooling system, a radio, a slot, a port, or a combination thereof operably coupled to the motherboard.

In one example, there is provided a method for making an electronic device package comprising obtaining a substrate, mounting an electronic component on the substrate, the electronic component being operable to generate heat due to resistance of electric current, and having a first peripheral portion, thermally coupling a heat spreader to the electronic component, the heat spreader being operable to transfer heat from the electronic component to a lateral location beyond the first peripheral portion, disposing an electronic device about a top side of the electronic component, such that the electronic device is supported by the substrate, the electronic device having a second peripheral portion that extends laterally beyond the first peripheral portion, and thermally coupling a thermal conduit to the heat spreader at the lateral location, the thermal conduit being operable to transfer heat away from the substrate.

In one example of a method for making an electronic device package, the lateral location is proximate the second peripheral portion.

In one example of a method for making an electronic device package, the thermal conduit is operable to transfer heat from the heat spreader toward the second peripheral portion.

In one example of a method for making an electronic device package, the heat spreader comprises a contact pad that interfaces with the thermal conduit.

In one example of a method for making an electronic device package, the heat spreader comprises a layer of thermally conductive material.

In one example of a method for making an electronic device package, the layer of thermally conductive material is disposed at least on the substrate.

In one example of a method for making an electronic device package, the layer of thermally conductive material is disposed on the electronic component.

In one example of a method for making an electronic device package, the thermally conductive material comprises copper, silver, gold, iron, graphite, graphene, diamond, or a combination thereof.

In one example of a method for making an electronic device package, the layer of thermally conductive material has a thickness of from about 50 μm to about 100 μm.

In one example of a method for making an electronic device package, a projected area of the heat spreader onto the substrate is at least 50% of a top surface area of the substrate.

In one example of a method for making an electronic device package, the heat spreader comprises a cover with a top portion and a side portion defining a recess that receives at least a portion of the electronic component therein.

In one example of a method for making an electronic device package, the top portion is proximate to a top surface of the electronic component.

In one example, a method for making an electronic device package comprises disposing thermal interface material (TIM) between the top surface of the electronic component and the top portion of the cover to facilitate heat transfer therebetween.

In one example of a method for making an electronic device package, the cover is made of copper, silver, gold, iron, graphite, graphene, diamond, or a combination thereof.

In one example of a method for making an electronic device package, the thermal conduit comprises at least one solder ball.

In one example of a method for making an electronic device package, the at least one solder ball comprises a ground solder ball, a dummy solder ball, or a combination thereof.

In one example, a method for making an electronic device package comprises disposing a second heat spreader about the electronic device, and thermally coupling the second heat spreader to the thermal conduit.

In one example of a method for making an electronic device package, the second heat spreader is disposed about at least a lateral side of the electronic device.

In one example of a method for making an electronic device package, the second heat spreader is disposed about a top side of the electronic device.

In one example of a method for making an electronic device package, the second heat spreader comprises a contact pad that interfaces with the thermal conduit.

In one example of a method for making an electronic device package, the contact pad is disposed on a bottom side of the electronic device.

In one example of a method for making an electronic device package, the second heat spreader comprises a layer of thermally conductive material.

In one example of a method for making an electronic device package, the layer of thermally conductive material is disposed at least on a lateral side of the electronic device.

In one example of a method for making an electronic device package, the layer of thermally conductive material is disposed on a top side of the electronic device.

In one example of a method for making an electronic device package, the thermally conductive material comprises copper, silver, gold, iron, graphite, graphene, diamond, or a combination thereof.

In one example of a method for making an electronic device package, the layer of thermally conductive material has a thickness of from about 50 μm to about 100 μm.

In one example, a method for making an electronic device package comprises disposing an encapsulant material between the substrate and the electronic device.

In one example of a method for making an electronic device package, the encapsulant material comprises a mold compound material.

In one example of a method for making an electronic device package, the mold compound material comprises an epoxy.

In one example of a method for making an electronic device package, the electronic component comprises a processor.

In one example of a method for making an electronic device package, the electronic component comprises an integrated circuit.

In one example of a method for making an electronic device package, the electronic component comprises a system on a chip (SOC).

In one example of a method for making an electronic device package, the electronic device comprises a second substrate and a second electronic component mounted on the second substrate.

In one example of a method for making an electronic device package, the electronic device comprises computer memory.

In one example of a method for making an electronic device package, the electronic device comprises a plurality of electronic components.

In one example, a method for making an electronic device package comprises electrically coupling the electronic device and the substrate with interconnect structures.

In one example of a method for making an electronic device package, the interconnect structures comprise solder balls.

In one example, a method for making an electronic device package comprises coupling interconnect structures to a bottom side of the substrate to facilitate electrically coupling the electronic device package with an external electronic component.

In one example of a method for making an electronic device package, the interconnect structures comprise solder balls.

Circuitry used in electronic components or devices (e.g. a die) of an electronic device package can include hardware, firmware, program code, executable code, computer instructions, and/or software. Electronic components and devices can include a non-transitory computer readable storage medium which can be a computer readable storage medium that does not include signal. In the case of program code execution on programmable computers, the computing devices recited herein may include a processor, a storage medium readable by the processor (including volatile and non-volatile memory and/or storage elements), at least one input device, and at least one output device. Volatile and non-volatile memory and/or storage elements may be a RAM, EPROM, flash drive, optical drive, magnetic hard drive, solid state drive, or other medium for storing electronic data. Node and wireless devices may also include a transceiver module, a counter module, a processing module, and/or a clock module or timer module. One or more programs that may implement or utilize any techniques described herein may use an application programming interface (API), reusable controls, and the like. Such programs may be implemented in a high level procedural or object oriented programming language to communicate with a computer system. However, the program(s) may be implemented in assembly or machine language, if desired. In any case, the language may be a compiled or interpreted language, and combined with hardware implementations.

While the forgoing examples are illustrative of the specific embodiments in one or more particular applications, it will be apparent to those of ordinary skill in the art that numerous modifications in form, usage and details of implementation can be made without departing from the principles and concepts articulated herein.

1. An electronic device package, comprising:
a substrate;
an electronic component mounted on the substrate and operable to generate heat due to resistance of electric current, the electronic component having a first peripheral portion;
an electronic device supported by the substrate and disposed about a top side of the electronic component, the electronic device having a second peripheral portion that extends laterally equal to or beyond the first peripheral portion;
a heat spreader disposed between the electronic component and the electronic device in thermal communication with the electronic component, the heat spreader being operable to transfer heat from the electronic component to a lateral location beyond the first peripheral portion; and
a thermal conduit thermally coupled to the heat spreader at the lateral location and operable to transfer heat away from the substrate, wherein the thermal conduit is an inactive thermal conduit that is configured to not carry an electrical current or signal.

2. The electronic device package of claim 1, wherein the lateral location is proximate the second peripheral portion.

3. The electronic device package of claim 1, wherein the heat spreader comprises a contact pad that interfaces with the thermal conduit.

4. The electronic device package of claim 1, wherein the heat spreader comprises a layer of thermally conductive material.

5. The electronic device package of claim 1, wherein a projected area of the heat spreader onto the substrate is at least 50% of a top surface area of the substrate.

6. The electronic device package of claim 1, wherein the heat spreader comprises a cover with a top portion and a side portion defining a recess that receives at least a portion of the electronic component therein.

7. The electronic device package of claim 1, wherein the thermal conduit comprises at least one solder ball.

8. The electronic device package of claim 1, further comprising a second heat spreader disposed about the electronic device and thermally coupled to the thermal conduit.

9. The electronic device package of claim 1, further comprising an encapsulant material disposed between the substrate and the electronic device.

10. The electronic device package of claim 9, wherein the encapsulant material comprises a mold compound material.

11. The electronic device package of claim 1, wherein the electronic component comprises a processor.

12. The electronic device package of claim 1, wherein the electronic component comprises an integrated circuit.

13. The electronic device package of claim 1, wherein the electronic component comprises a system on a chip (SOC).

14. The electronic device package of claim 1, wherein the electronic device comprises a second substrate and a second electronic component mounted on the second substrate.

15. The electronic device package of claim 1, wherein the electronic device comprises computer memory.

16. The electronic device package of claim 1, wherein the electronic device comprises a plurality of electronic components.

17. The electronic device package of claim 1, further comprising interconnect structures electrically coupling the electronic device with the substrate.

18. The electronic device package of claim 17, wherein the interconnect structures comprise solder balls.

19. The electronic device package of claim 1, further comprising interconnect structures coupled to a bottom side of the substrate to facilitate electrically coupling the electronic device package with an external electronic component.

20. The electronic device package of claim 19, wherein the interconnect structures comprise solder balls.

21. A method for making an electronic device package, comprising:
obtaining a substrate;
mounting an electronic component on the substrate, the electronic component being operable to generate heat due to resistance of electric current, and having a first peripheral portion;
thermally coupling a heat spreader to the electronic component, the heat spreader being operable to transfer heat from the electronic component to a lateral location beyond the first peripheral portion;
disposing an electronic device about a top side of the electronic component, such that the electronic device is supported by the substrate, the electronic device having a second peripheral portion that extends laterally equal to or beyond the first peripheral portion; and
thermally coupling a thermal conduit to the heat spreader at the lateral location, the thermal conduit being operable to transfer heat away from the substrate, wherein the thermal conduit is an inactive thermal conduit that is configured to not carry an electrical current or signal.

22. The method of claim 21, wherein the heat spreader comprises a contact pad that interfaces with the thermal conduit.

23. The method of claim 21, wherein the heat spreader comprises a cover with a top portion and a side portion defining a recess that receives at least a portion of the electronic component therein.

24. The method of claim 21, wherein the thermal conduit comprises at least one solder ball.

25. The method of claim 21, further comprising disposing a second heat spreader about the electronic device, and thermally coupling the second heat spreader to the thermal conduit.

26. The method of claim 21, further comprising disposing an encapsulant material between the substrate and the electronic device.

27. The method of claim 21, further comprising electrically coupling the electronic device and the substrate with interconnect structures.

28. The method of claim 21, further comprising coupling interconnect structures to a bottom side of the substrate to facilitate electrically coupling the electronic device package with an external electronic component.

29. The electronic device package of claim 1, wherein the second peripheral portion extends laterally beyond the first peripheral portion and the thermal conduit is further coupled to the second peripheral portion of the electronic device.

30. The electronic device package of claim 8, wherein the second heat spreader is disposed about a lateral side of the electronic device, and wherein a portion of the second heat spreader is disposed between the second peripheral portion and the lateral location.

31. The method of claim 21, further comprising coupling the thermal conduit to the second peripheral portion of the electronic device, wherein the second peripheral portion extends laterally beyond the first peripheral portion.

32. The method of claim 25, further comprising disposing the second heat spreader about a lateral side of the electronic device, wherein a portion of the second heat spreader is disposed between the second peripheral portion and the lateral location.
